(19) United States
(12) Patent Application Publication
(10) Pub. No.: US 2012/0135641 A1
(43) Pub. Date: May 31, 2012

(54) CONNECTOR AND METHOD OF COUPLING THE SAME TO SUBSTRATE

(75) Inventors: Takeshi Okuyama, Tokyo (JP); Tadashi Kumamoto, Tokyo (JP); Kazuhiro Mizukami, Tokyo (JP)

(73) Assignee: FUJITSU COMPONENT LIMITED, Tokyo (JP)

(21) Appl. No.: 13/304,445

(22) Filed: Nov. 25, 2011

(30) Foreign Application Priority Data
Nov. 30, 2010 (JP) 2010-267445

(51) Int. Cl. H01R 24/28; H05K 3/30

(52) U.S. Cl. 439/626; 29/842

(57) ABSTRACT

A disclosed connector includes a signal contact whose first end portion is to be connected to a connection terminal of another connector, wherein the signal contact is formed of an electrically conductive material; an insulating part including a groove part in which a second end portion of the signal contact is placed; a floating lead that is placed in the groove part and movable in a longitudinal direction of the groove part, wherein first end portion of the floating lead is to be in contact with the second end portion of the signal contact placed in the groove part; and a solder member adapted to electrically connect the first portion of the floating lead and the second end portion of the signal contact.

### CROSS-REFERENCE TO RELATED APPLICATIONS

This application is based upon and claims the benefit of priority of the prior Japanese Patent Application No. 2010-267445, filed on Nov. 30, 2010, the entire contents of which are incorporated herein by reference.

### FIELD

The present invention relates to a connector that electrically connects an electric device with an electric apparatus and the like.

### BACKGROUND

Connectors have been widely used as electric connection parts that electrically connect an electric device with an electric apparatus and the like thereby to allow electrical communications between the electrical apparatus and the electrical apparatus and like (see U.S. Pat. No. 6,986,682, for example). Various types of connectors are developed and used depending on their usage.

Such connectors usually have two or more connection terminals. Among the two or more connection terminals, the connection terminals of one connector are to be connected with corresponding connection terminals of another connector, and the connection terminals of the other connector are to be solder-connected and thus fixed to corresponding connection terminals provided on a substrate such as a printed circuit board or the like.

### SUMMARY

In a connector so configured, it is rather difficult to arrange the connection terminals to be solder-connected at accurately identical clearances with respect to the corresponding connection terminals of the substrate. In addition, because an upper surface where the connection terminals of the substrate are formed is not always completely flat, some of the connection terminals of the connector are not in contact with the corresponding connection terminals of the substrate, while the other connection terminals of the connector are in contact with the corresponding connection terminals of the substrate. Under such circumstances, the connection terminals of the connector may not be appropriately solder-connected to the connection terminals of the substrate.

The present invention has been made in view of the above, and provides a connector wherein solder connection between the connector and a substrate is improved.

An aspect of the present invention provides a connector including a signal contact whose first end portion is to be connected to a connection terminal of another connector, wherein the signal contact is formed of an electrically conductive material; an insulating part including a groove part in which a second end portion of the signal contact is placed; a floating lead that is placed in the groove part and is movable in a longitudinal direction of the groove part, wherein a first end portion of the floating lead is to be in contact with the second end portion of the signal contact placed in the groove part; and a solder member adapted to electrically connect the first portion of the floating lead and the second end portion of the signal contact.

The object and advantages of the invention will be realized and attained by means of the elements and combinations particularly pointed out in the claims.

It is to be understood that both the foregoing general description and the following detailed description are exemplary and explanatory and are not restrictive of the invention as claimed.

### BRIEF DESCRIPTION OF DRAWING

FIG. 1 is an exploded perspective view of a connector according to a first embodiment of the present invention;

FIG. 2 is a perspective view of the connecter according to the first embodiment;

FIG. 3 is a plan view of the connecter according to the first embodiment;

FIG. 4 is a cross-sectional view of the connecter according to the first embodiment;

FIG. 5 is another cross-sectional view of the connecter according to the first embodiment;

FIG. 6 is yet another cross-sectional view of the connecter according to the first embodiment;

FIG. 7 is a plan view of the connecter according to the first embodiment, where a solder ball is omitted for the sake of explanation;

FIG. 8 is another plan view of the connecter according to the first embodiment, where a solder ball is omitted for the sake of explanation;

FIG. 9 is yet another plan view of the connecter according to the first embodiment, where a solder ball is omitted for the sake of explanation;

FIG. 10 is a plan view of an alteration of the connecter according to the first embodiment;

FIG. 11 is a cross-sectional view of another alteration of the connecter according to the first embodiment;

FIG. 12 is a cross-sectional view of yet another alteration of the connecter according to the first embodiment;

FIG. 13 is a perspective view of an alteration of the connector according to the first embodiment;

FIG. 14 is a perspective view of another alteration of the connector according to the first embodiment;

FIG. 15 is a perspective view of yet another alteration of the connector according to the first embodiment;

FIG. 16 is a cross-sectional view of an alteration of the connection according to the first embodiment;

FIG. 17 is an exploded perspective view of a connector according to a second embodiment of the present invention;

FIG. 18 is a perspective view of the connector according to the second embodiment of the present invention; and

FIG. 19 is an enlarged perspective view of a primary part of the connector according to the second embodiment of the present invention.

### DESCRIPTION OF EMBODIMENT(S)

According to an embodiment of the present invention, there is provided a connector wherein solder connection between the connector and a substrate is improved.

Non-limiting, exemplary embodiments of the present invention will now be described with reference to the accompanying drawings. In the drawings, the same or corresponding reference symbols are given to the same or corresponding members or components. It is to be noted that the drawings are illustrative of the invention, and there is no intention to indicate scale or relative proportions among the members or components. Therefore, the specific size should be determined by a person having ordinary skill in the art in view of the following non-limiting embodiments.

### First Embodiment

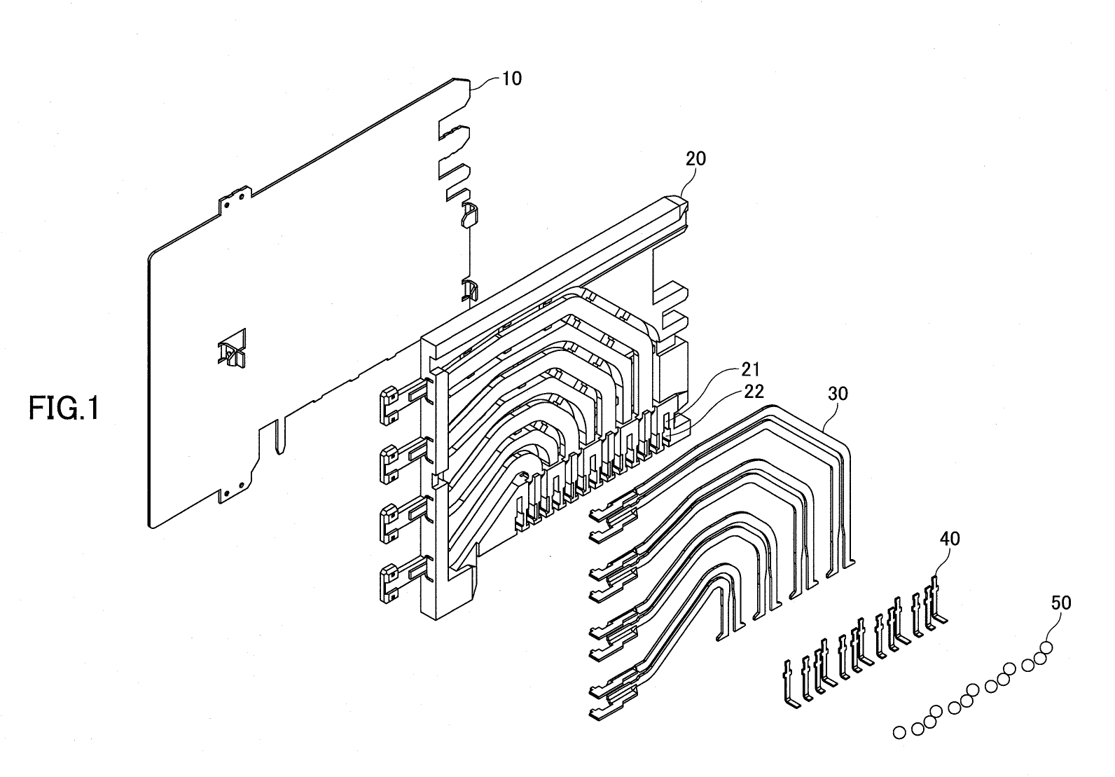

A connector according to a first embodiment is explained with reference to FIG. 1. A connector according to this embodiment includes a plate-like ground (GND) part 10, an insulating part 20, plural signal contacts 30, plural floating leads 40, and solder balls 50 serving as solder members.

The signal contacts 30 and the floating leads 40 are made of electrically conductive material.

Plural groove parts 21 are formed in a front surface of the insulating part 20, and the plural signal contacts 30 and the floating leads 40 are housed in the corresponding groove parts 21. Widths of the groove parts 21 are slightly wider than those of the floating leads 40 so that the floating leads 40 can slide along longitudinal directions of the groove parts 21 in the corresponding groove parts 21. In addition, the groove parts 21 are open at one edge portion of the insulating part 20, so that the floating leads 40 protrude in part from the edge portion of the insulating part 20.

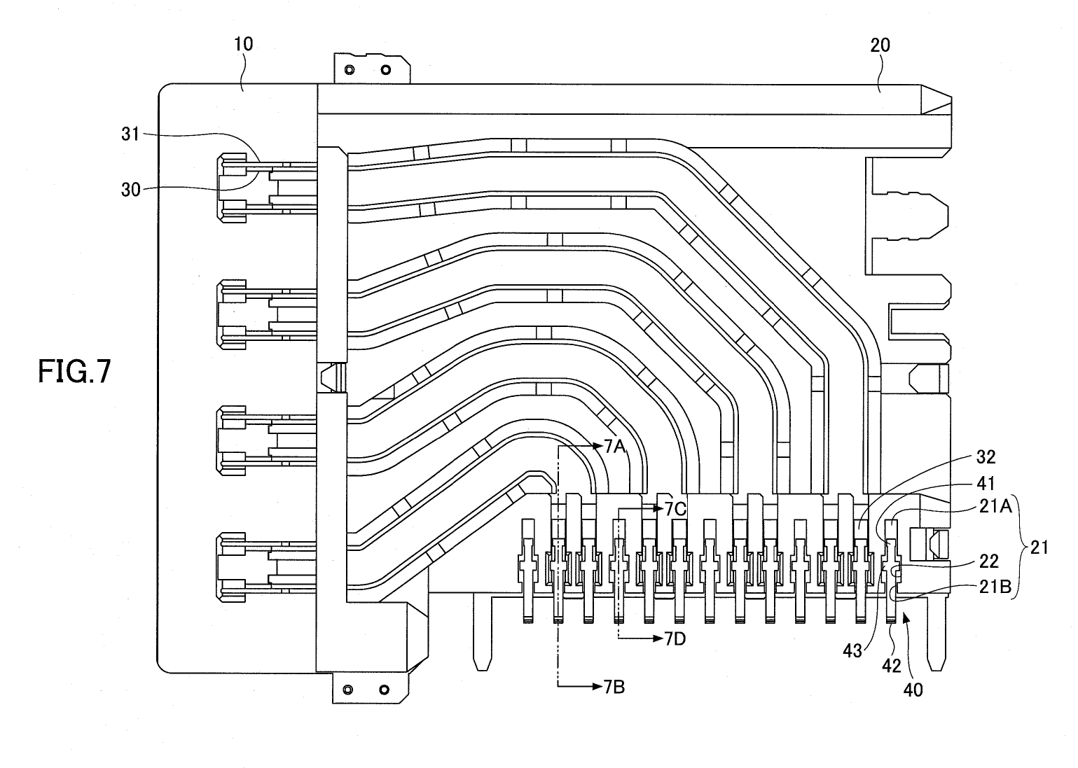

Moreover, portions of the groove parts 21 become wider so that there are formed wider groove parts 22 that are wider than the groove parts 21. In other words, each of the groove parts 21 has a first narrow groove part 21A, the wider groove part 22 wider than the first narrow groove part 21A, and a second narrow groove part 21B having substantially the same width as the first narrow groove part 21A. The first narrow groove part 21A, the wider groove part 22, and the second narrow groove part 21B are formed in this order in the longitudinal direction of the groove part 21, as best illustrated in FIG. 7. In the wider groove parts 22, the corresponding solder balls 50 are housed thereby to be positioned on or above the corresponding floating leads 40.

In addition, the GND part 10 to be connected to ground is attached on the other surface (reverse surface) of the insulating part 20. In other words, the wider groove parts 22 receive the corresponding solder balls 50 so that the floating leads 40 and the solder balls 50 are placed in this order on the corresponding signal contacts 30 in the wider groove parts 22.

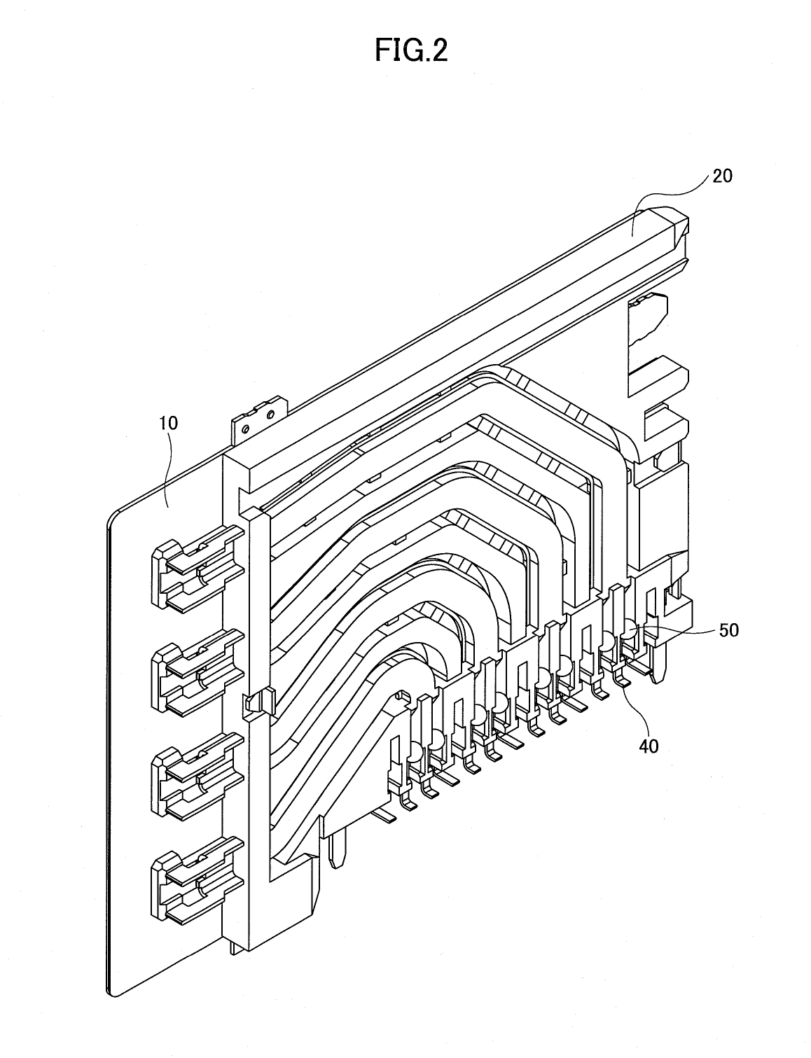

FIG. 2 illustrates the connector so configured. Two or more of the connectors are stacked one on another in a housing part (not illustrated), and thus the connector unit is formed.

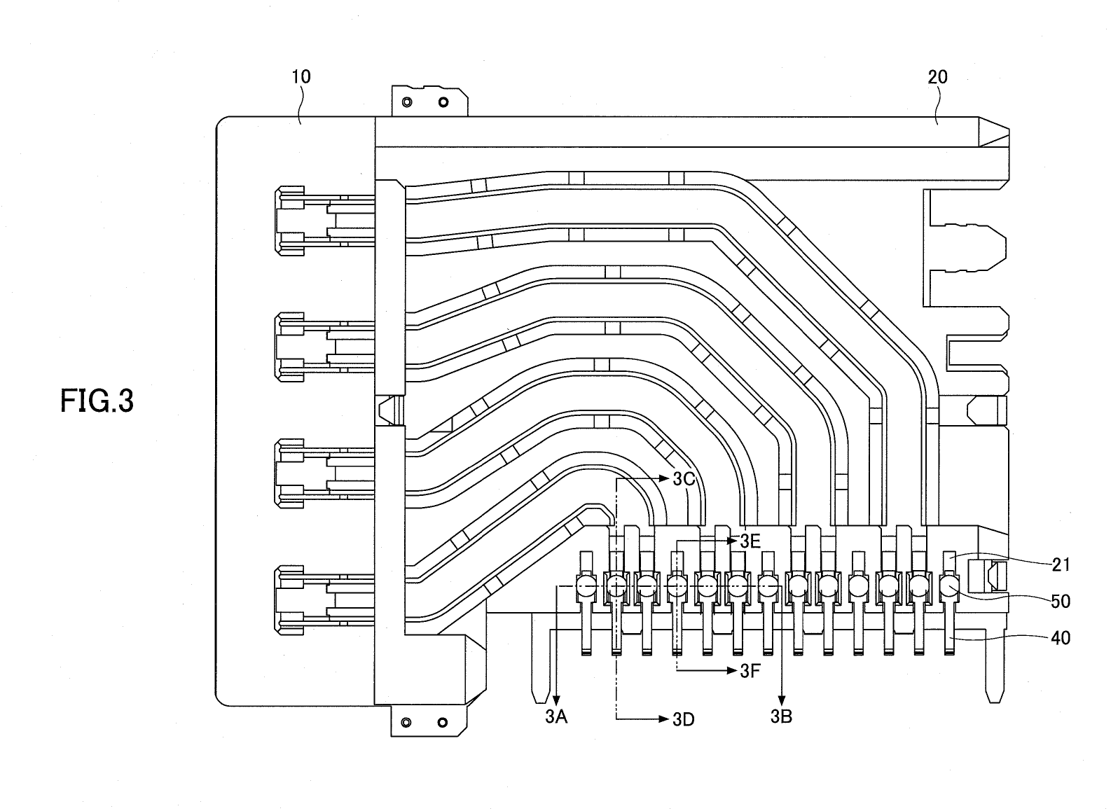

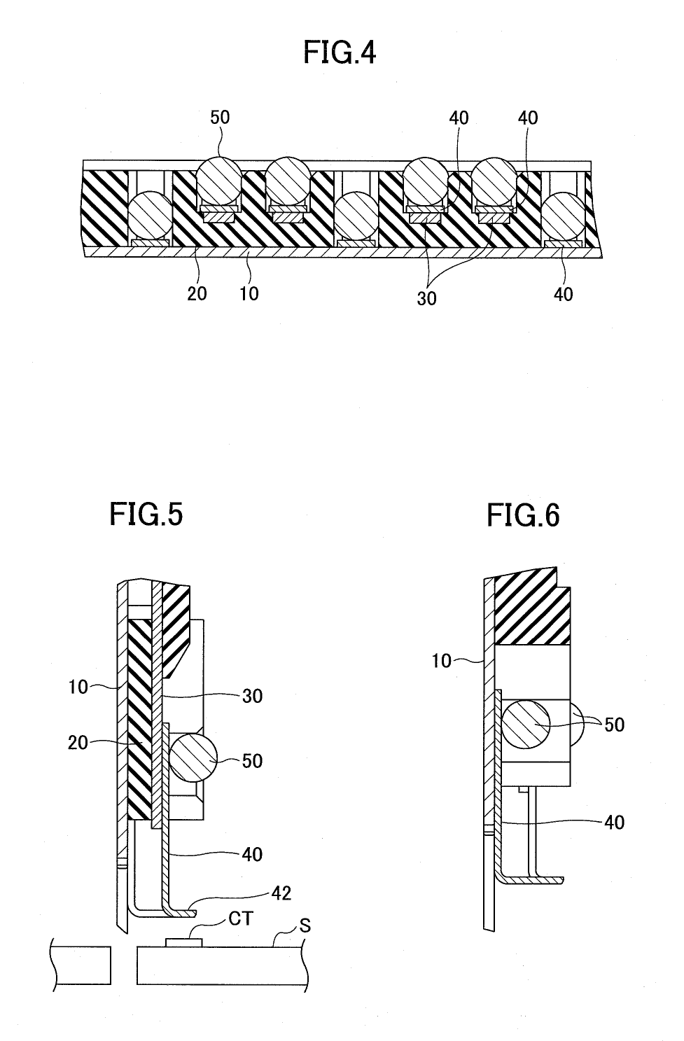

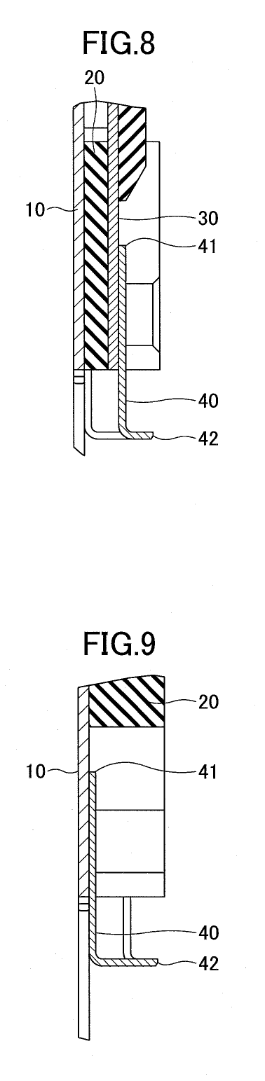

The connector according to this embodiment is explained in detail with reference to FIGS. 3 through 9. FIG. 3 is a plan view of the connector according to this embodiment; FIG. 4 is a cross-sectional view taken along 3A-3B two-dot chain line in FIG. 3; FIG. 5 is a cross-sectional view taken along 3C-3D two-dot chain line in FIG. 3; FIG. 6 is a cross-sectional view taken along 3E-3F two-dot chain line in FIG. 3; FIG. 7 is a plan view of the connector according to this embodiment, without the solder balls 50; FIG. 8 is a cross-sectional view taken along 7A-7B two-dot chain line in FIG. 7; and FIG. 9 is a cross-sectional view taken along 7C-7D two-dot chain line in FIG. 7.

In the connector according to this embodiment, the signal contacts 30 and the floating leads 40 are arranged in this order in the corresponding groove parts 21 formed on the front surface of the insulating part 20. The solder balls 50 are placed on or above the floating leads 50 in the corresponding wider groove parts 22. The GND part 10 is attached on the reverse surface of the insulating part 20.

First end portions 31 of the corresponding signal contacts 30 are to be connected (see FIG. 7) to corresponding portions of another connector. Four pairs of the two signal contacts 30 (namely eight signal contacts 30) are formed in the connector illustrated in FIGS. 3 and 7. The signal contacts 30 are curved substantially throughout their lengths so that the first end portions 31 extend in a direction substantially orthogonal to a direction along which second end portions 32 of the signal contacts 30 extend.

The floating leads 40 are to be connected to connection terminals provided in a substrate such as a printed circuit board (refer to FIG. 5 for a connection terminal CT and a substrate S in FIG. 5). As illustrated in FIGS. 3 and 7, there are thirteen floating leads 40. Among them, four pairs of the two floating leads 40 (namely eight floating leads 40) are connected to the corresponding first end portions 31 of the signal contacts 30, and five of the floating leads 40 are connected to the GND part 10, as illustrated in FIGS. 4 and 6. Specifically, first end portions 41 (see FIGS. 8 and 9) of the floating leads 40 are solder-connected to the corresponding signal contacts 30 or the GND part 10 by heating and melting the corresponding solder balls 50. Second end portions 42 of the floating leads 40 are to be connected to the connection terminals of the substrate. Incidentally, the floating leads 40 have an L-shape, and thus the second end portions 42 are substantially parallel with an upper surface of the substrate, as illustrated in FIG. 5.

As illustrated in FIG. 7, the floating lead 40 has protrusion portions that protrude in directions substantially perpendicular to a longitudinal direction of the floating lead 40, so that a cross-shape part 43 is formed between the first end portion 41 and the second end portion 42 of the floating lead 40. A width of the cross-shape part 43 is slightly narrower than that of the wider groove part 22, which is formed within the corresponding groove part 21 in the insulating parts 20, so that the cross-shape part 43 can be housed in the wider groove part 22. Specifically, the cross-shape part 43 is narrower than the wider groove part 22 and wider than the groove part 21. In addition, a length of the cross-shape part 43 along the longitudinal direction of the floating lead 40 is shorter than that of the wider groove part 22 along the longitudinal direction of the groove part 21. Therefore, the cross-shape part 43 can move within the wider groove part 22, and thus the cross-shape 43 allows the floating lead 40 to slide with respect to the groove part 21 within a predetermined range.

When the connector is arranged so that a direction along which the floating leads 40 extend is substantially perpendicular to the substrate (see FIG. 5), and the second end portions 42 of the floating leads 40 are allowed to be in contact with the corresponding connection terminals of the substrate, the floating leads 40 can change their heights depending on roughness of the upper surface of the substrate, and thus the second end portions 42 are certainly in contact with the corresponding connection terminals of the substrate. In this case, when the solder balls 50 are heated, melted, and then cooled to be solidified, the first end portions 41 of the floating leads 40 are solder-connected to the corresponding second end portions 32 of the signal contacts 30, while the second end portions 42 of the floating leads 40 are in contact with the corresponding connection terminals of the substrate. At the same time or subsequently, when the second end portions 42 of the floating leads 40 are solder-connected to the corresponding connection terminals of the substrate, the second end portions 42 and the corresponding connection terminals of the substrate can be certainly solder-connected, because the second end portions 42 of the floating leads 40 are in contact with the corresponding connection terminals of the substrate at the time of solder connecting.

In other words, when the connector is arranged so that a direction from the first end portions 41 to the second end portions 42 of the floating leads 40 are along the direction of gravity, the floating leads 40 are moved to their lowermost positions without contacting the connection terminals of the substrate. At this time, the cross-shape part 43 comes in contact with an inner wall of the wider groove part 22, the inner wall defining a boundary between the wider groove part 22 and the second narrow groove part 21B (see FIG. 3). Next, the connector is moved downward and then the second end portions 42 of the floating leads 40 come in contact with the corresponding connection terminals of the substrate. At this time, when the floating leads 40 are allowed to freely move with respect to the corresponding groove parts 21 or the connector, all the floating leads 40 can be certainly in contact with the corresponding connection terminals of the substrate.

The solder balls 50 are made of solder and have ball shapes. A diameter of the solder balls 50 is a slightly larger than the width of the wider groove part 22 of the insulating part 20. Therefore, when the solder balls 50 are inserted by pressure into the corresponding wider groove part 22 of the insulating part 20, the solder balls 50 can stay in the wider groove parts 22, and thus the signal contacts 30, the floating leads 40, and the solder balls 50 are not removed out from the groove part 21 (the narrow groove parts 21A, 21B and the wider groove parts 22) even when the connector according to this embodiment is conveyed or transported.

While the solder balls 50 are used in this embodiment, thread solder, ribbon solder, paste solder, or the like may be used in other embodiments. In addition, the solder ball 50, the thread solder, ribbon solder, paste solder, or the like may contain flux. Moreover, a low temperature solder containing tin, bismuth, indium, or the like may be used instead of the solder ball 50 in other embodiments.

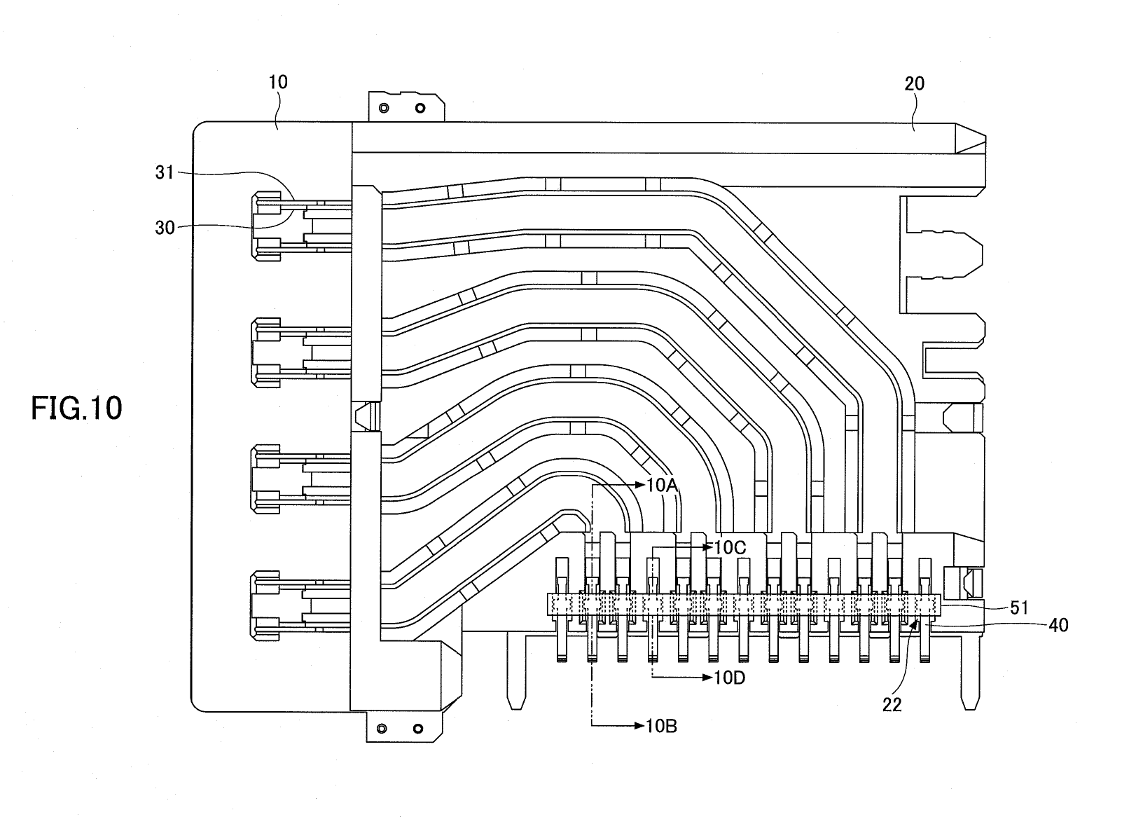

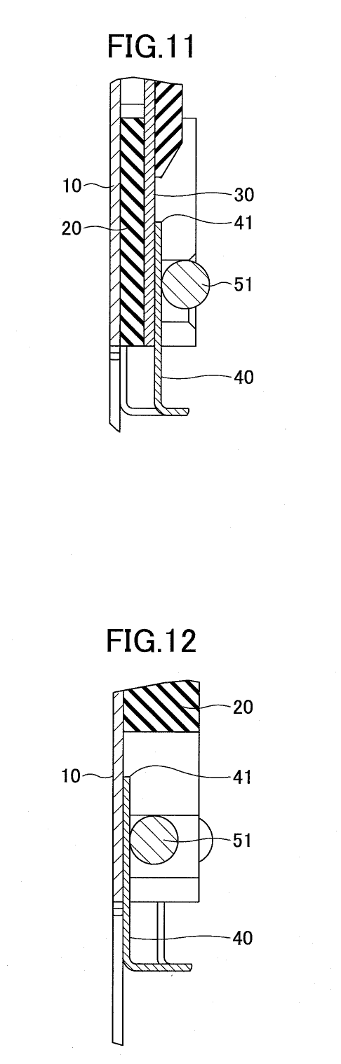

Moreover, the thread solder may be arranged so that the thread solder extends in a direction perpendicular to the longitudinal direction of the floating lead 40, as illustrated in FIGS. 10 through 12. FIG. 10 is a plan view of the connector and the thread solder; FIG. 11 is a cross-sectional view taken along a two-dot chain line 10A-10B; and FIG. 12 is a cross-sectional view taken along a two-dot chain line 10C-10D.

Specifically, a thread solder 51 extends in a direction substantially perpendicular to the longitudinal directions of the groove parts 21 thereby to cover the wider groove parts 22. The thread solder 51 is held on the insulating part 20 by a holding member (not illustrated). In addition, a solder-repellant (or solder-nonwettable) material is applied to an area of the upper surface of the insulating part 20, the area being between the wider groove parts 22. When the thread solder 51 is melted and then solidified, the thread solder 51 electrically connects the first end portions 41 of the floating leads 40 and the second end portions 32 of the signal contacts 30 mainly in the corresponding wider groove parts 22. In this case, the area to which the solder repellent material is applied repels the melted thread solder, so that the melted and then solidified solder does not cause short-circuits between the adjacent floating leads 40.

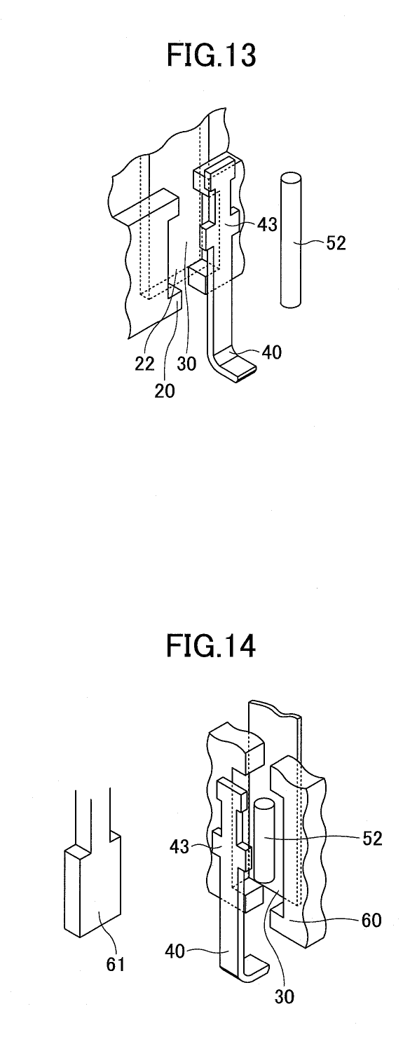

In addition, a connector according to another embodiment may have a thread solder 52 that has a predetermined length and is placed in the wider groove part 22 where the cross-shape part 43 is positioned, as shown in FIG. 13.

In addition, a connector according to yet another embodiment may have an insulating part 60 having an opening corresponding to the cross-shape part 43 of the floating lead 40. Specifically, the thread solder 52 and the floating lead 40 are placed in this order on the signal contact 30 so that the cross-shape part 43 is positioned in the opening. In addition, a cover member 61 made of an insulating material is placed on the floating lead 40.

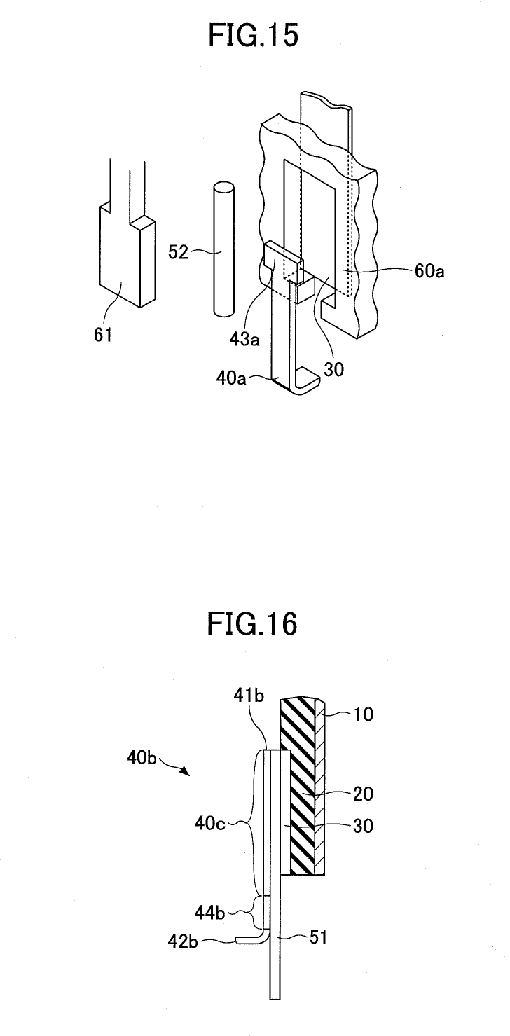

Moreover, a connector according to still another embodiment may have a floating lead 40a that includes two protrusions on both sides of the top end of the floating lead 40a, thereby to form a T-shape end portion 43a, as illustrated in FIG. 15. The T-shape end portion 43a has a wider width than the other part of the floating lead 40a. In addition, the connector has an insulating part 60a having an opening in which the T-shape end portion 43a is housed so that the T-shape end portion 43a does not prevent the floating lead 40 from moving in the longitudinal direction of the floating lead 40. When the floating lead 40a with the T-shape end portion 43a is used, an upper portion of the opening in the insulating part 60a may be closed as illustrated in FIG. 15.

Moreover, the floating lead 40a is placed on the signal contact 30 in the opening of the insulating part 60a, and the thread solder 52 is placed on the floating lead 40 in the illustrated example. Furthermore, the cover member 61 made of an insulating material is placed on the thread solder 52.

Incidentally, while the cover member 61 made of an insulating material is explained above, an adhesive tape or the like made of, for example, polyimide or the like may be used instead of the cover member 61. In this case, the thread solder 52 and the like can be adhered on and thus assuredly supported by the adhesive tape.

Moreover, a floating lead 40b including a solder-repellant area 44b, as illustrated in FIG. 16, may be used in other embodiments. Specifically, the solder-repellant area 44b is formed between a first end portion 41b and a second end portion 42b of the floating lead 40b. More specifically, the solder-repellant area 44b is formed adjacent to the second end portion 42b, and an upper area 40c excluding the solder-repellant area 44b and the second end portion 42b can be electrically connected to the signal contact 30. In addition, the thread solder 51 and the floating lead 40b are arranged in this order on the signal contact 30 as illustrated in FIG. 16. With such a configuration, when the connector having the floating leads 40b is attached to the substrate, the upper areas 40c of the floating leads 40b are solder-connected to the corresponding signal contacts 30, and the second end portions 42b of the floating leads 40b are solder-connected to the corresponding connection terminals of the substrate. In this case, the solder-repellent area 44b repels melted solder, and thus no solder remains in the solder-repellent area 44b. The solder-repellent area 44b may be made by applying nickel (Ni), a solder-repellent resin, or the like thereto.

### Second Embodiment

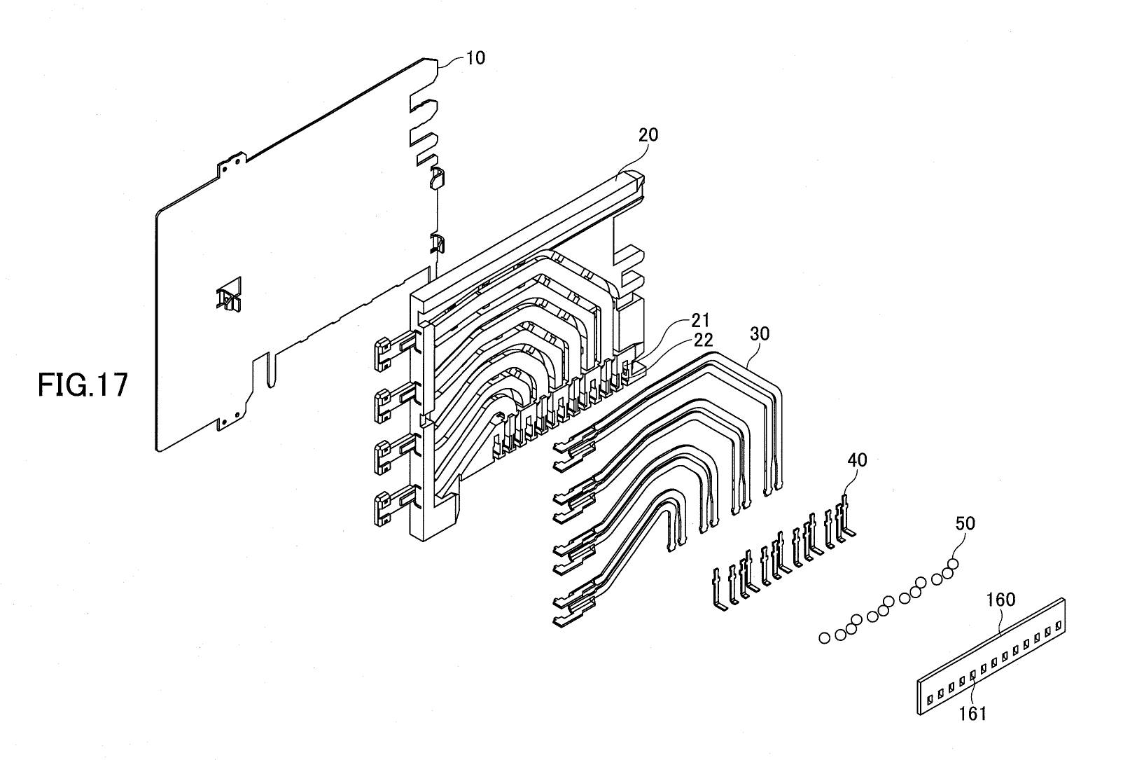

Next, a connector according to a second embodiment of the present invention is explained with respect to FIGS. 17 through 19. The connector according to this embodiment has substantially the same configuration as the connector according to the first embodiment, except that the second embodiment is provided with a solder holding cover member 160, as understood by comparing FIG. 1 and FIG. 17. Specifically, the solder holding cover member 160 is arranged on the insulating part 20 in order to cover the groove parts 21 thereby to hold the solder balls 50, as illustrated in FIG. 17. With the solder holding cover member 160, the solder balls 50 are not removed from the wider groove part 22 (FIG. 17), even if the solder balls 50 have diameters smaller than the width of the wider groove part 22.

On the other hand, the solder ball cover member 160 has plural openings 161, as illustrated in FIG. 19. The openings 161 are formed corresponding to the wider groove parts 22 and thus the solder balls 50. The openings 161 allow the corresponding solder balls 50 to be visibly recognized to be in the corresponding wider groove parts 22. In addition, although plan view shapes of the openings 161 are squares in the illustrated example, the openings 161 may have circular top view shapes. Moreover, sizes of the openings 161 are preferably smaller than the diameters of the corresponding solder balls 50, in order to prevent the solder balls 50 from being removed from the corresponding wider groove parts 22.

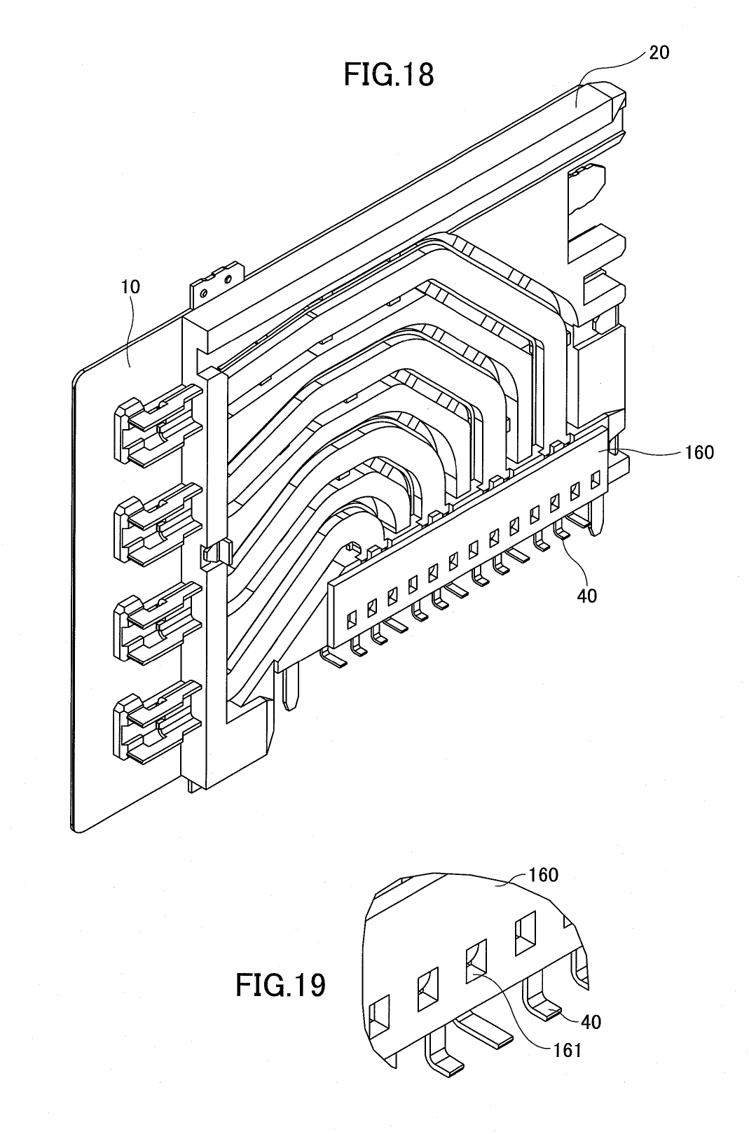

FIG. 18 illustrates the connector so configured. Two or more of the connectors are stacked one on another in a housing part (not illustrated), and thus the connector unit is formed.

While the present invention has been described in reference to the foregoing embodiments, the present invention is not limited to the disclosed embodiments, but may be modified or altered within the scope of the accompanying claims.

For example, when the connector according to embodiments of the present invention is coupled to the substrate such as a printed circuit board, the connector is held perpendicular to the substrate laid flat in the above explanation. However, the connector may be laid flat and the substrate is held perpendicular to the connector. In this case, the connecter and the substrate are relatively horizontally moved closer to each other, so that the second end portions 42 (or 42b) assuredly come in contact with the corresponding connection terminals of the substrate. This is because the floating leads (or 40a, 40b) can be movable with respect to the corresponding groove parts 21.

What is claimed is:

1. A connector comprising:
a signal contact whose first end portion is to be connected to a connection terminal of another connector, wherein the signal contact is formed of an electrically conductive material;
an insulating part including a groove part in which a second end portion of the signal contact is placed;
a floating lead that is placed in the groove part and is movable in a longitudinal direction of the groove part, wherein a first end portion of the floating lead is to be in contact with the second end portion of the signal contact placed in the groove part; and
a solder member adapted to electrically connect the first portion of the floating lead and the second end portion of the signal contact.

2. The connector of claim 1, wherein the solder member comprises one of thread solder, ribbon solder, paste solder, solder ball, and low temperature solder.

3. The connector of claim 1, wherein the solder member electrically connects the first portion of the floating lead and the second end portion of the signal contact after the solder member is melted and then solidified.

4. The connector of claim 1, wherein the floating lead includes protrusions thereby to form a wide portion that is wider than other parts of the floating lead and
wherein the groove part includes a wide groove part that is wider than other parts of the groove part so that the wide portion of the floating lead is movably housed in the wide groove part.

5. The connector of claim 4, wherein the floating lead and the solder member are arranged in this order on the signal contact in the wide width part.

6. The connector of claim 4, further comprising a cover member that is made of electrically insulating material and covers the wider groove part.

7. The connector of claim 5, further comprising a cover member that is placed on or above the solder member and includes an opening positioned corresponding to the wider groove part.

8. The connector of claim 4, wherein the solder member is larger than the wider groove part to an extent so that the solder member is inserted by pressure into the wider groove part.

9. The connector of claim 4, wherein the solder member is a solder ball having a diameter larger than a width of the wider groove part.

10. A coupling method that electrically couples a connector to a substrate, the method comprising steps of:
preparing a connector recited in claim 1 and a substrate to which the connector is coupled;
holding the connector substantially perpendicular to the substrate so that the second end portions of the floating lead oppose corresponding connection terminals of the substrate with a predetermined distance kept between the second end portions of the floating lead and the connection terminals of the substrate;
moving the connector and the substrate closer to each other until the second end portions of the floating lead come in contact with the corresponding connection terminals of the substrate;
connecting the first end portions of the floating lead to the corresponding second end portion of the signal contact by melting and then solidifying the solder member; and
electrically connecting the second end portions of the floating lead to the corresponding connection terminals of the substrate.

11. The coupling method of claim 10, further comprising a step of laying the substrate flat, wherein the connector is held so that a direction from the first end portion to the second end portion of the floating lead is along the direction of gravity.
